(19) United States
(12) Patent Application Publication
(10) Pub. No.: US 2003/0087514 A1
(43) Pub. Date: May 8, 2003

(54) Hard mask damascene process used to form a semiconductor device

(76) Inventors: Sanh Dang Tang, Boise, ID (US); James Mathew, Boise, ID (US)

Correspondence Address: Micron Technology, Inc., c/o Kevin D. Martin, Patent Department, MS 525, 8000 S. Federal Way, Boise, ID, 83716, US

(21) Appl. No.: 10/007,929

(22) Filed: Nov. 2, 2001

(51) Int. Cl. H01L 21/4763

(52) U.S. Cl. 438/630

(57) ABSTRACT

A method used to form a semiconductor device comprises patterning a hard mask layer with a first pattern, then only partially etching through an underlying dielectric layer using the hard mask as a pattern. Next, the hard mask is patterned with a second pattern and the dielectric layer is completely etched through using the hard mask as a pattern. The dielectric etch stops on an etch stop layer. Finally, the etch stop layer is patterned which is defined only by the first pattern of the hard mask.

### FIELD OF THE INVENTION

This invention relates to the field of semiconductor manufacture, and more particularly to a method for forming a contact to an underlying conductive structure such as a copper runner or interconnect.

### BACKGROUND OF THE INVENTION

During the manufacture of semiconductor devices such as dynamic random access memories (DRAMs), static random access memories (SRAMs), magnetic random access memories (MRAMs), embedded memory, microprocessors, and logic devices, various features are commonly formed. For example, conductive runners and interconnects (hereinafter, collectively, “interconnects”) are formed to route a signal or data bit from one location on a semiconductor wafer substrate assembly to another location. Further, contacts to the conductive interconnect are often formed to route the signal carried by the interconnect to a different level on the semiconductor wafer substrate assembly.

FIGS. 1-5 depict a conventional method for providing a contact to a copper interconnect. FIG. 1 depicts a semiconductor wafer substrate assembly 8 comprising a semiconductor wafer 10, a dielectric layer 12 such as silicon dioxide (SiO₂), and copper interconnects 14, 15 between about 2,000 angstroms (2 KÅ) and about 4 KÅ thick formed according to means known in the art. The wafer assembly 8 will likely comprise additional features which are not separately depicted, such as doped regions, transistors, and storage capacitors. In this embodiment, a tantalum nitride dielectric 16 between about 100 Å and 300 Å thick, and generally about 200 Å thick, functions as a diffusion barrier to prevent the diffusion of copper from interconnects 14, 15 into the SiO₂ layer 12. Other materials used for barrier 16 include heavy transition metals such as tantalum and tungsten.

FIG. 1 further depicts a barrier layer 18 between 200 Å and 500 Å thick and generally about 300 Å thick, such as silicon nitride (Si₃N₄) or silicon oxycarbide (SiOC), and an interlayer dielectric (ILD) 20, for example tetraethyl orthosilicate (TEOS) about 11 KÅ thick, overlying the copper interconnects 14, 15. The barrier layer 18 is an insulating diffusion barrier which prevents oxidation of the copper interconnects 14, 15 during deposition of TEOS 20, and also prevents migration of copper from interconnects 14, 15 into the dielectric 20. In general, there should be an etch selectivity higher than about 3:1 between the ILD 20 and the barrier 18. A photoresist (resist) layer 22 defines an opening 24, for example between about 0.15 micrometers (μm) and about 0.30 μm wide which allows exposure of interconnect 14 in subsequent processing steps.

The interlayer dielectric 20 and barrier layer 18 are etched according to means known in the art to leave the structure of FIG. 2 including a contact opening 24 to the interconnect 14. A polymer 26 is typically formed within the opening during the etch, which is subsequently stripped along with the photoresist layer 22.

After stripping the polymer 26 and photoresist 22, a second photoresist layer 30 is formed over the wafer substrate assembly as depicted in FIG. 3. Typically a spun-on blanket layer, the photoresist is deposited within the contact opening. Resist portion 32 is exposed using standard photolithography techniques. Due to the relatively small diameter of the opening and the thickness of the resist layer, it is difficult to expose the resist portion 34 at the bottom of the contact opening, and this portion often remains unexposed. Further, a portion of polymer 26 can remain from the previous attempt at polymer removal between FIGS. 2 and 3. If an aggressive etch is used to remove the polymer 26 and resist 34, the copper 14 can be damaged.

Subsequent to exposing the resist 30, the exposed portion 32 is removed to provide the pattern as depicted in FIG. 4. The resist will define an opening 40 between about 0.17 μm wide and greater than about 0.30 μm wide which will be used to further pattern the TEOS 20. A timed oxide etch is performed according to means known in the art to pattern the TEOS as depicted in FIG. 5, then the resist 30 is removed. Resist removal is done using means which will not damage the copper interconnect 14, and as such any resist 34 remaining on the bottom of the via may not be adequately removed. For example, a preferred etch which removes the unexposed resist and minimizes damage to the copper interconnect includes a no oxygen etch such as ammonia (NH₃) at 300° C., hydrofluoric acid, a low temperature oxide etch, or a plasma etch. Next, a layer 50 is formed from a material such as tantalum or tantalum nitride between about 100 Å and about 300 Å thick as a barrier to prevent copper diffusion. A thin copper seed layer 52 between about 700 Å and about 2 KÅ thick is formed, for example using chemical vapor deposition (CVD) or high density physical vapor deposition (PVD). Subsequently a thick conductive material 54 such as copper is formed such as by electroplating or CVD to provide a blanket layer within opening 40. Finally, layer 54 is planarized, for example using mechanical polishing such as chemical mechanical polishing, to result in the structure of FIG. 6 which may be a damascene runner 60 as depicted, a conductive plug, or another such conductive structure.

The intent of conductive structure 60 is to provide a conductive contact to interconnect 14 and a damascene runner, but due to the remaining resist 34 and polymer 26 within the opening, electrical contact between structure 60 and interconnect 14 is not made. A device is thereby produced which, at best, has decreased electrical properties and more likely will be nonfunctional.

If an aggressive etch is attempted on the structure of FIG. 4 to remove the resist 34 and the polymer 26 to ensure that the interconnect is exposed, for example using a mixture of sulfuric acid (H₂SO₄) and hydrogen peroxide (H₂O₂), the interconnect 14 can be damaged by even a slight over etch.

A method for providing a contact which reduces or eliminates the problems described above would be desirable.

### SUMMARY OF THE INVENTION

The present invention provides a new method which, among other advantages, reduces problems associated with the manufacture of semiconductor devices, particularly problems resulting from the formation of resist within a deep, narrow opening such as a contact opening or damascene runner opening to an underlying conductive layer. In accordance with one embodiment of the invention a semiconductor wafer substrate assembly is provided which comprises a conductive structure such as a copper interconnect to which contact is to be made. A barrier layer is provided over the interconnect, and an interlayer dielectric (ILD) is formed over the barrier layer and over the interconnect. Next, a hard mask layer, preferably an amorphous silicon layer or a polycrystalline silicon (polysilicon) layer, is formed over the ILD, and a first patterned resist layer is formed over the hard mask layer. A vertical anisotropic etch patterns the hard mask layer and removes a portion of the ILD over the feature to which contact is to be made. This etch provides a portion of a contact opening within the ILD, while leaving the barrier layer and a portion of the ILD between the etched opening and the barrier layer unetched. Any polymer formed during the dielectric etch can be removed using an aggressive etch, as a portion of the dielectric layer and the barrier layer remain to protect the interconnect. Subsequently, the first resist layer is removed, and a second resist layer is formed over surface of the wafer substrate assembly. A portion of the second resist layer is undesirably but necessarily deposited within the contact opening. The second resist layer is patterned, subsequent to which a portion of the second resist layer often remains in the contact opening due to a high aspect ratio of the opening. Next, the hard mask layer is etched using the second resist layer as a pattern, then the second resist layer is removed.

A more aggressive cleaning step can be used on both the first and second resist layers than with conventional processes as the underlying feature to which contact is to be made is protected by the remaining ILD and by the barrier layer. After removing the resist the remaining ILD layer over the feature and the barrier layer are etched to expose the feature, and a conductive layer is formed within the opening.

Additional advantages will become apparent to those skilled in the art from the following detailed description read in conjunction with the appended claims and the drawings attached hereto.

### BRIEF DESCRIPTION OF THE DRAWINGS

FIG. 1 is a cross section depicting a starting assembly with a conventional process to form a damascene runner to a copper runner;

FIG. 2 is a cross section of the FIG. 1 structure subsequent to etching an interlayer dielectric and a barrier layer;

FIG. 3 is a cross section of the FIG. 2 structure after forming and exposing a resist layer;

FIG. 4 is a cross section of the FIG. 3 structure after removing the exposed resist layer portion;

FIG. 5 depicts the structure of FIG. 4 after etching the interlayer dielectric and forming a blanket conductive layer;

FIG. 6 depicts the FIG. 5 structure after planarizing the surface of the FIG. 5 structure;

FIG. 7 is a cross section of a starting structure used with an embodiment of the instant inventive process, and comprises a patterned first resist layer;

FIG. 8 is a cross section of a structure which results from a timed etch of the FIG. 7 structure and depicts a partially etched opening and resulting cross-sectional polymer spacers;

FIG. 9 is a cross section of the FIG. 8 structure after removing the polymer spacers and after forming a blanket second resist layer;

FIG. 10 depicts the FIG. 9 structure subsequent to exposing the blanket second resist layer and removing the exposed portion, which results in a portion of the resist remaining in the bottom of the opening;

FIG. 11 depicts the FIG. 10 structure after patterning a hard mask layer;

FIG. 12 is a cross section of the FIG. 11 structure after removing the resist layer from over the dielectric and from within the opening using an aggressive etch;

FIG. 13 depicts the FIG. 12 structure after again etching the ILD and after etching the underlying barrier layer to expose the copper runner;

FIG. 14 depicts the FIG. 13 structure after forming a conductive layer within the opening in the ILD; and

FIG. 15 depicts the FIG. 14 structure after planarizing the conductive layer to form a damascene runner and contact plug.

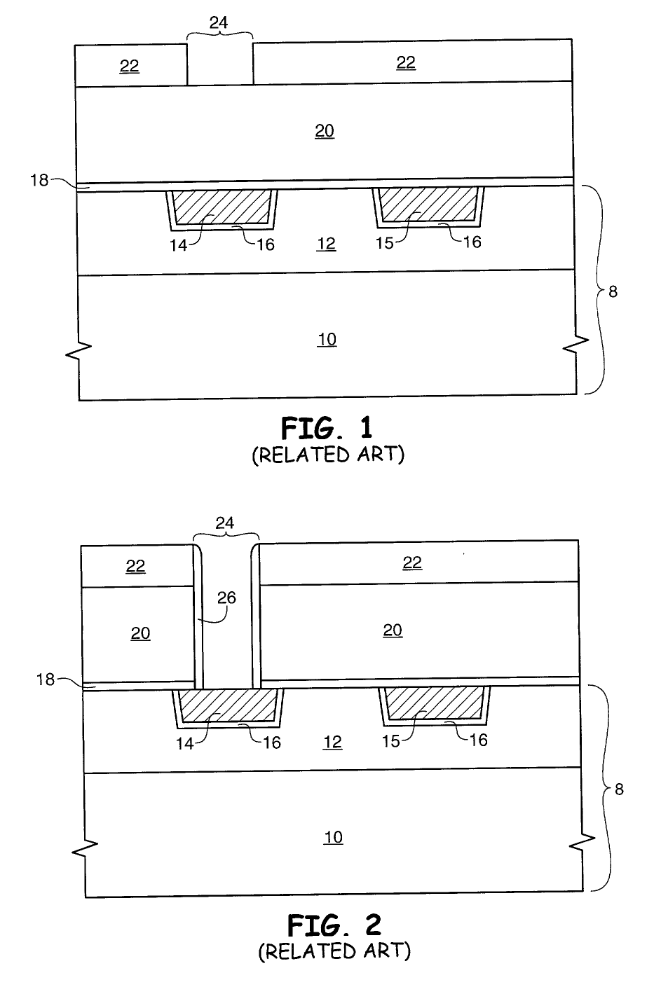

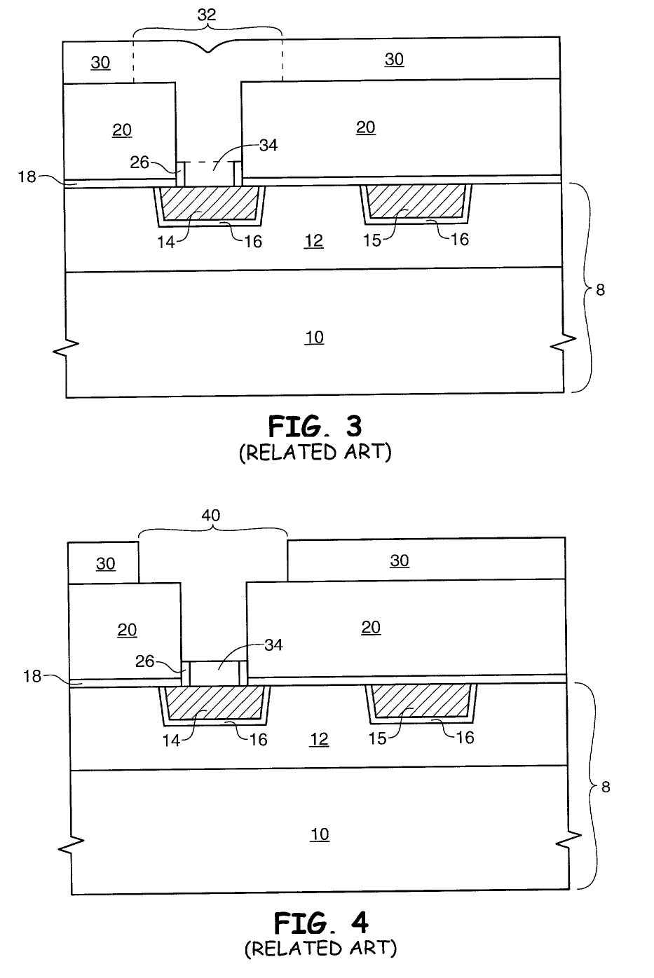

It should be emphasized that the drawings herein may not be to exact scale and are schematic representations. The drawings are not intended to portray the specific parameters, materials, particular uses, or the structural details of the invention, which can be determined by one of skill in the art by examination of the information herein.

### DETAILED DESCRIPTION OF THE PREFERRED EMBODIMENT

A first embodiment of an inventive method for forming a semiconductor device is depicted in FIGS. 7-15. FIG. 7 depicts a semiconductor wafer substrate assembly 8 comprising a semiconductor wafer 10, a silicon dioxide dielectric layer 12, and first 14 and second 15 conductive interconnects. In this embodiment the interconnects are manufactured from copper or copper alloy. A tantalum nitride layer (TaN) 16 functions as a diffusion barrier to prevent the diffusion of copper metal from the interconnects 14, 15 into dielectric layer 12. With current processing technology, copper interconnects 14, 15 will be about 2000 angstroms (2 KÅ) wide and about 3 KÅ thick and the TaN layer will be about 150 Å thick.

A blanket etch stop layer, for example a layer of silicon nitride 18 between about 200 Å and about 500 Å thick is deposited over the wafer surface, including the copper interconnects 14, 15. This layer also functions as a diffusion barrier layer to prevent the migration of copper metal from interconnects 14, 15 into layer 20. Other materials may function adequately for the etch stop layer, but sufficient materials will be nonconductive or minimally conductive and will allow for etching of overlying layer 20 with little or no etching itself. A dielectric layer 20, for example a tetraethyl orthosilicate (TEOS) layer between about 6 KÅ and about 15 KÅ thick, typically about 11 KÅ thick, is deposited over the silicon nitride layer 18.

Next, a hard mask layer 70 is formed over the planar surface of the dielectric layer. The hard mask material will allow for etching of the dielectric layer 20 and the etch stop layer 18 with little or no etching itself. Suitable materials for layer 70 include amorphous silicon, tungsten silicide (WSiₓ), tungsten nitride (WN), tungsten silicon nitride (WSiN), titanium nitride (TiN), tantalum (Ta), tantalum nitride (TaN), or generally any stable film which has a lower etch rate than layer 20 using a selected etch. Layer 70 can be formed between about 500 Å and about 2 KÅ thick. Such a layer of amorphous silicon can be formed over the planar dielectric layer 20 using chemical vapor deposition (CVD) by introducing silane gas (SiH₄) at a temperature of about 400° C. into a deposition chamber within which the wafer substrate assembly is located, and will form in between about 7.5 minutes and about 30 minutes.

After forming the hard mask layer, a first patterned photoresist (resist) layer 72 is formed over the surface of the hard mask. Resist 72 defines an opening 74 to interconnect 14 with a first pattern. In this embodiment interconnect 15 will not be exposed using the mask 72 depicted in FIG. 7, for example, but may be similarly exposed at another cross-sectional location.

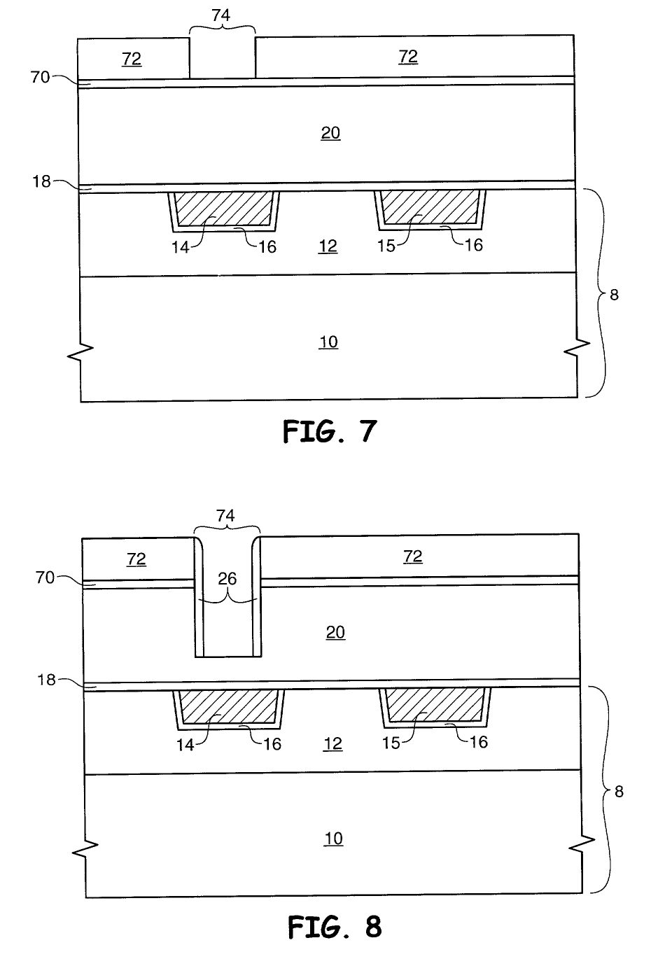

Subsequent to forming resist 72, the portion of hard mask layer 70 exposed at 74 is removed, for example using a low pressure, high power etch of Cl₂ and HBr to produce a rapid, anisotropic etch. Additional etch parameters include a flow rate of 60 standard cm³ (sccm) Cl₂ and 20 sccm HBr, a pressure of about 10 to about 20 millitorr, a power of about 250 watts to about 350 watts. Using these etch parameters the hard mask will etch at a rate of about 20 Å/second. After etching the hard mask to form an opening therein at 74, the dielectric layer 20 is etched using the hard mask 70 as a pattern to result in the structure of FIG. 8. In this embodiment the resist 72 remains in place during the etch of dielectric 20. The etch which results in the FIG. 8 structure only partially etches through the TEOS layer 20, for example between about 60% and about 90% of the way through the total thickness. For an 11,000 Å thick layer of TEOS as described above, between about 6,600 Å and about 9,900 Å can be removed, thereby leaving an oxide thickness of between about 1,100 Å and about 4,400 Å. In general, enough oxide should remain so that any polymer which forms during the etch of oxide 20 can be aggressively etched without risking exposure and etching of copper interconnect 14. The oxide 20 can be etched selective to hard mask 70 using CF₄ at a flow rate of between about 50 sccm and about 100 sccm, CHF₃ at a flow rate of between about 10 sccm and about 20 sccm, and argon at a flow rate of between about 50 sccm and about 100 sccm to provide a vertical etch. In the alternative, the TEOS 20 may be etched in process which varies a CF₄:CHF₃ ratio. This dielectric etch forms a cross-sectional opening in the dielectric layer having a width, in this embodiment, of between about 0.15 μm and about 0.3 μm. Etching the FIG. 7 structure also results in cross-sectional polymer spacers 26, which are built up as depicted in FIG. 8.

After etching the hard mask 70 and the dielectric 20 to result in the FIG. 8 structure, the photoresist 72 and the polymer 26 are removed. The resist 72 can be removed using conventional methods. Because a portion of dielectric layer 20 remains over the etch stop layer 18 an aggressive removal of the polymer can be implemented without concern for damaging interconnect 14, for example using a mixture of H₂SO₄ and H₂O₂ without exposing the copper to the etch.

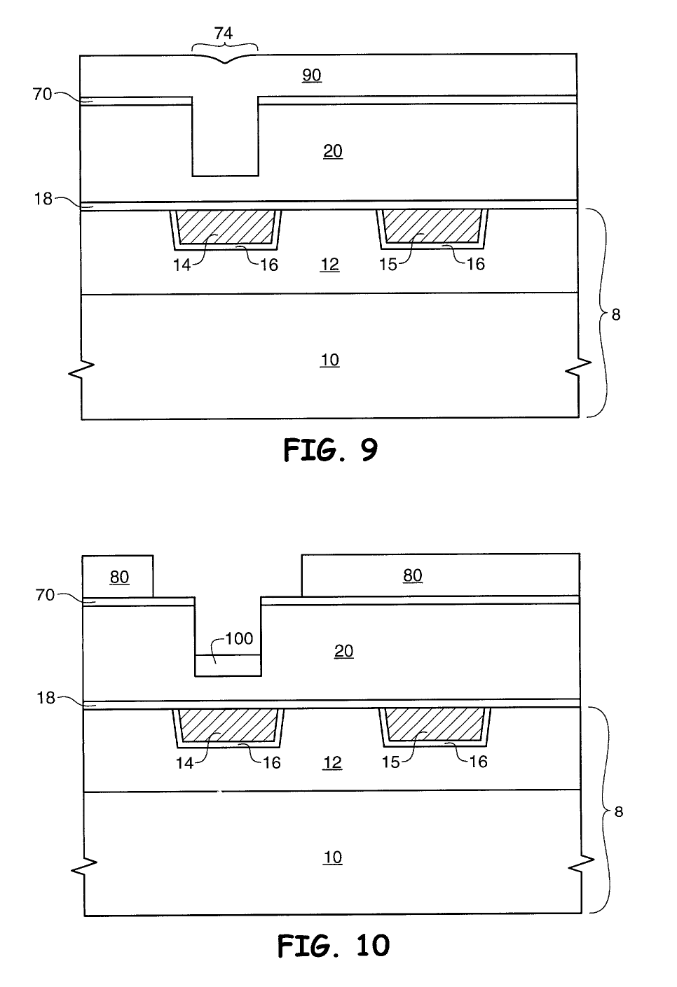

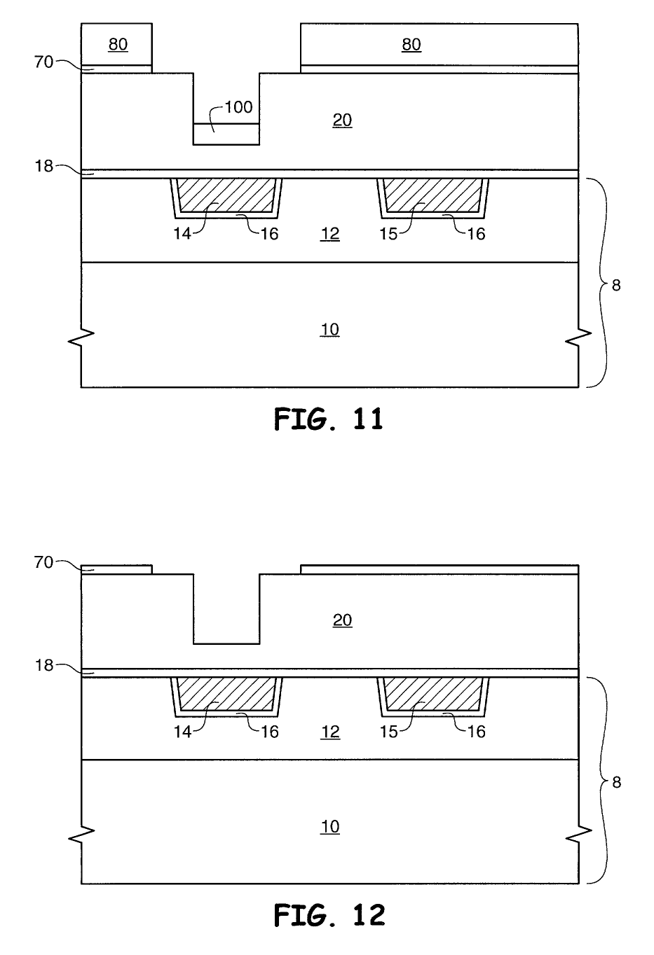

Subsequently, a blanket second resist layer 90, such as spun-on resist, is formed as depicted in FIG. 9. The resist layer is undesirably but necessarily deposited within opening 74. The resist is exposed according to means known in the art and the exposed portion is removed to form the structure of FIG. 10. Due to the high aspect ratio of the opening, a portion of the resist 100 may remain in the opening, for example because it is not exposed due to the thickness of the overlying resist within the opening during exposure, or because of difficulty in removing the material from the high-aspect opening. After patterning the resist as depicted in FIG. 10, the hard mask 70 is etched, for example using the etch described above for the previous patterning etch of the hard mask, to form a second pattern (contrasted with the first pattern of layer 70 as depicted in FIG. 9) and results in the structure of FIG. 11. This etch of the hard mask results in little or no etching of the dielectric 20 or the photoresist material 100 within the opening in the dielectric.

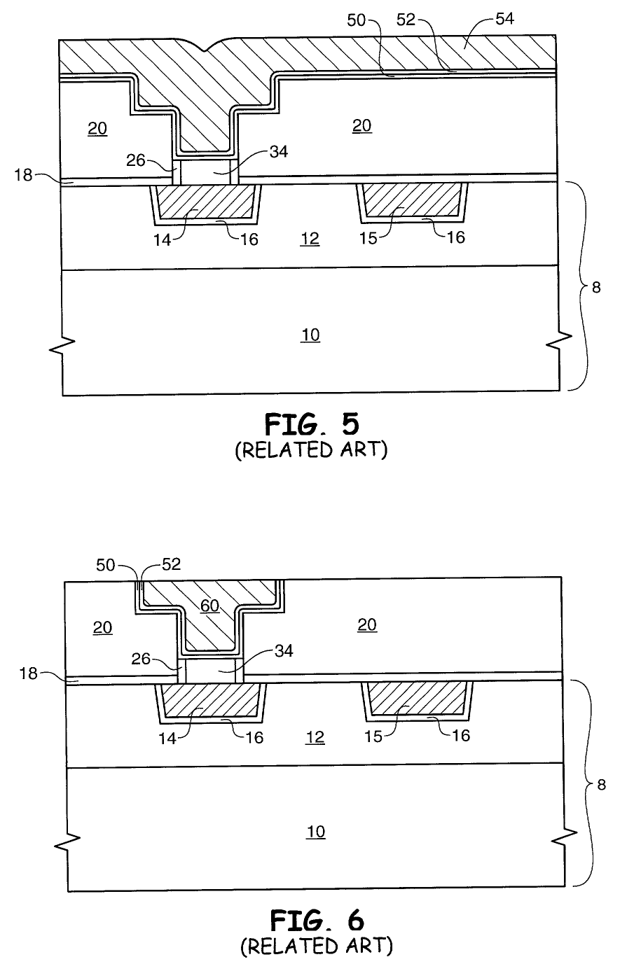

After etching the hard mask, the photoresist 90, 100 is removed to result in the structure of FIG. 12. Because a portion of dielectric layer 20 remains over the etch stop layer 18 an aggressive removal of the photoresist can be implemented without concern for damaging interconnect 14. For example, a dry plasma etch using O₂ at a flow rate of between about 500 sccm and about 5,000 sccm, N₂H₂ at a flow rate of between about 100 sccm and about 300 sccm, and NH₃ at a flow rate of between about 500 sccm and about 2,000 sccm can be performed. This can be followed by a wet etch using phosphoric acid (H₃PO₄), for example a 20:1 dip (H₂O:H₃PO₄) for a duration of about 180 seconds at a temperature of between about 30° C. and about 40° C., or hydrofluoric acid (HF), for example a 300:1 dip (H₂O:HF) for a duration of about 30 seconds with the temperature at ambient. This aggressive etch would not be possible in conventional processing, for example on the structure of FIG. 4, as interconnects 14, 15, particularly copper interconnects, can be damaged by aggressive etches of the photoresist as described above once the resist is removed and the interconnects are exposed to the etchants.

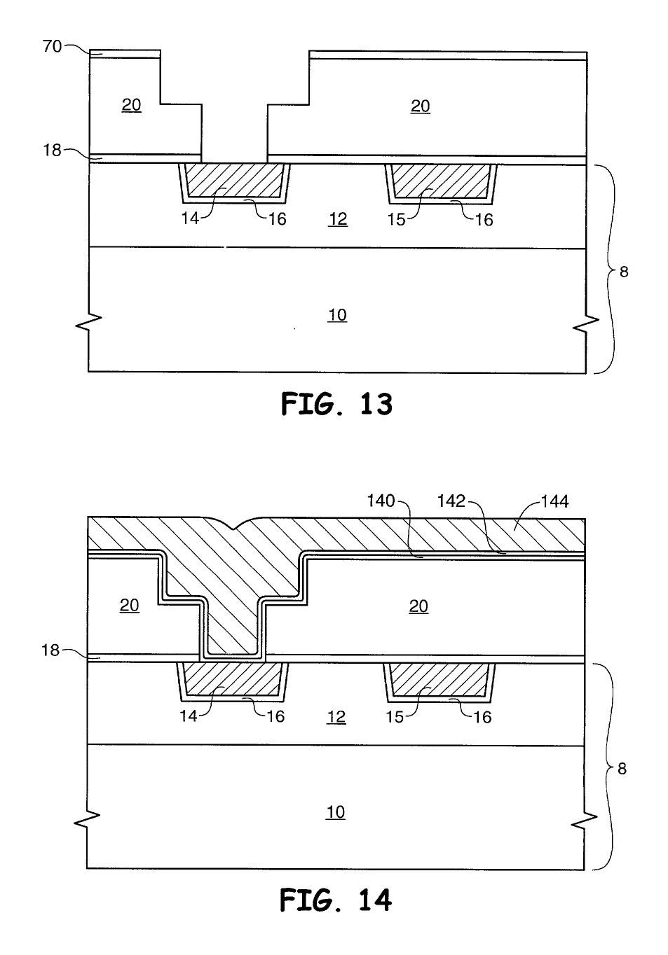

After forming the FIG. 12 structure, a timed etch is performed on the oxide 20 using the hard mask 70 as a pattern to etch completely through the dielectric layer 20 as depicted in FIG. 13. For example, the TEOS can be etched using the etch described above selective to a polysilicon hard mask 70 using CF₄ at a flow rate of between about 50 sccm and about 100 sccm, CHF₃ at a flow rate of between about 10 sccm and about 20 sccm, and argon at a flow rate of between about 50 sccm and about 100 sccm at a pressure of about 20 millitorr to about 50 millitorr, a power of about 600 watts to about 1,000 watts to provide a vertical etch. As this etches the TEOS at a rate of about 3,000 Å/minute the etch is performed for about 20 seconds to about 200 seconds for the 1,100 Å to 9,900 Å of TEOS as described above. This duration will likely be modified for each particular application of the invention and the etch system which is being used. This etch extends the first opening to layer 18 and forms an opening having a second cross-sectional width partially into the dielectric layer 20. The second width, for this embodiment, is between about 0.18 μm to greater than about 0.30 μm.

Further, the etch described above can be continued to remove diffusion barrier 18 as depicted in FIG. 13, or, once the diffusion barrier is exposed, a different etch which has a higher selectivity to copper than to the diffusion barrier (i.e. etches the copper at a slower rate) can be used, depending on the material selected as the diffusion barrier 18.

Optionally, the hard mask 70 is removed, for example with the low pressure, high power etch using Cl₂ and HBr as described above. Alternately (and more likely) the hard mask layer can be left in place and removed later as described below. In either case, a diffusion barrier layer 140 is formed from a material such as tantalum or tantalum nitride between about 100 Å and about 300 Å thick as a barrier to prevent copper diffusion. Next, a thin copper seed layer 142 between about 800 Å and about 2 KÅ thick is formed, for example using chemical vapor deposition (CVD) or high density physical vapor deposition (PVD). Subsequently a thick conductive material 144 such as copper is formed by electroplating or by CVD to provide a blanket layer within the opening in layer 20 to result in the FIG. 14 structure.

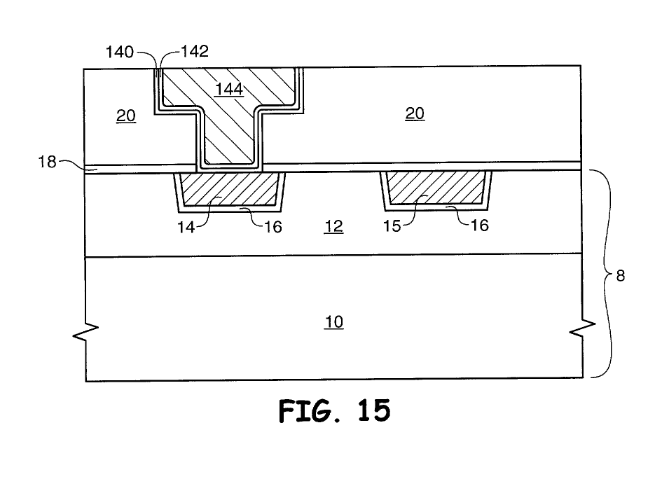

Finally, the thick conductive layer 144, the seed layer 142, the diffusion barrier layer 140, and, if present, the hard mask layer 70 are planarized, for example using mechanical polishing such as chemical mechanical polishing, to result in the structure of FIG. 15. The structure can provide a damascene runner and conductive plug as depicted, or another such conductive structure.

A semiconductor device formed using the invention may be attached along with other devices to a printed circuit board, for example to a computer motherboard or as a part of a memory module used in a personal computer, a minicomputer, or a mainframe. The inventive device may also be useful in other electronic devices related to telecommunications, the automobile industry, semiconductor test and manufacturing equipment, consumer electronics, or virtually any piece of consumer or industrial electronic equipment.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. It is therefore contemplated that the appended claims will cover any such modifications or embodiments as fall within the true scope of the invention.

What is claimed is:

1. A method used to form a semiconductor device comprising:
patterning a hard mask layer with a first pattern;
etching only partially through a dielectric layer using said hard mask as a pattern;
subsequent to etching only partially through said dielectric layer, patterning said hard mask layer with a second pattern;
subsequent to patterning said hard mask with said second pattern, etching completely through said dielectric layer using said hard mask as a pattern and stopping on an etch stop layer; and
subsequent to stopping on said etch stop layer, etching said etch stop layer with a pattern defined only by said first pattern of said hard mask.

2. The method of claim 1 wherein said patterning said hard mask layer with said first pattern comprises etching an amorphous hard mask layer.

3. The method of claim 2 wherein said etching of said etch stop layer comprises etching a tantalum nitride etch stop layer.

4. The method of claim 1 further comprising completely removing said first pattern prior to said etching only partially through said dielectric layer using said hard mask as a pattern.

5. A method used to form a semiconductor device comprising:
providing a semiconductor wafer substrate assembly comprising an interconnect, a dielectric layer overlying said interconnect, a hard mask overlying said dielectric layer, and a first patterned resist layer overlying said hard mask;
etching said hard mask and only partially through said dielectric layer using said first patterned resist layer as a pattern, wherein said etching forms an opening within said dielectric layer;
removing said first patterned resist layer;
forming a second patterned resist layer over said hard mask and within said opening in said dielectric layer;
etching said hard mask using said second patterned resist layer as a pattern; and
subsequent to etching said hard mask using said second patterned resist layer as a pattern, etching said dielectric layer using said hard mask as a pattern.

6. The method of claim 5 further comprising:
removing said first patterned resist layer prior to forming said second patterned resist layer,
wherein said etching of said dielectric layer subsequent to removing said second patterned resist layer comprises etching said dielectric layer with a hard mask pattern defined by said first patterned resist layer.

7. A method used to form a semiconductor device comprising:
providing a semiconductor wafer substrate assembly comprising a conductive interconnect;
forming a diffusion barrier layer over said interconnect;
forming a dielectric layer overlying said barrier layer;
forming a hard mask layer over said dielectric layer;
providing a first patterned resist layer having an opening therein, said opening overlying said interconnect;
patterning said hard mask layer using said first patterned resist layer as a pattern, said hard mask layer being a patterned hard mask layer subsequent to etching said hard mask layer;
only partially etching through said dielectric layer to provide an opening therein using said patterned hard mask as a pattern;
removing said first resist layer;
subsequent to removing said first resist layer, providing a second patterned resist layer over said patterned hard mask layer and within said opening in said dielectric layer;
etching said hard mask using said second resist layer as a pattern;
subsequent to patterning said hard mask using said second resist layer as a pattern, removing said second resist layer from over said hard mask and from within said opening in said dielectric layer; and
subsequent to removing said second resist layer, etching said dielectric layer to expose said diffusion barrier layer using said hard mask as a pattern.

8. The method of claim 7 wherein said etching of said dielectric layer to expose said barrier layer using said hard mask as a pattern etches said dielectric layer in a pattern defined by said patterned first mask layer and in a pattern defined by said patterned second mask layer simultaneously.

9. The method of claim 8 further comprising exposing said diffusion barrier layer in a pattern defined by said patterned first mask layer while etching said dielectric layer in a pattern defined by said patterned second mask layer.

10. A method used to form a semiconductor device comprising:
etching only partially through a dielectric layer at a first location using a hard mask having a first pattern to form a first opening in said dielectric layer;
forming a resist layer over said hard mask and within said opening;
etching said hard mask using said resist layer as a pattern;
removing said resist layer;
subsequent to removing said resist layer, etching completely through said dielectric layer at said first location and only partially etching into said dielectric layer at a second location using said hard mask as a pattern and exposing an etch stop layer at said first location; and
subsequent to etching completely through said dielectric layer at said first location, etching said etch stop layer to a pattern defined only by said first pattern of said hard mask.

11. The method of claim 10 wherein said formation of said first opening in said dielectric layer forms an opening having a first cross-sectional width and said etching into said dielectric layer at said second location forms an opening in said dielectric layer having a second cross-sectional width larger than said first width.

12. A method used to form a semiconductor device comprising:
providing a semiconductor substrate assembly having a conductive interconnect within a first dielectric layer;
forming a diffusion barrier over said semiconductor substrate assembly which contacts said first and second interconnects;
forming a second dielectric layer over said diffusion barrier;
forming a hard mask layer over said second dielectric layer;
forming a first patterned photoresist layer over said hard mask layer;
patterning said hard mask layer and only partially etching said second dielectric layer at a first location with said first photoresist layer to form an opening in said second dielectric layer; wherein a first polymer layer forms within said opening in said second dielectric layer and a portion of said dielectric layer remains at said first location;
etching said first polymer layer, wherein said diffusion barrier is not exposed subsequent to etching said first polymer layer;
forming a second patterned photoresist layer over said hard mask layer and within said opening in said second dielectric layer;
patterning said hard mask layer and further etching said second dielectric layer at said first location with said second patterned photoresist layer as a pattern to expose said diffusion barrier, wherein a second polymer layer form within said opening in said second dielectric layer;
etching said second polymer layer using said diffusion barrier as an etch stop layer; and
subsequent to etching said second polymer layer, etching said diffusion barrier to expose said conductive interconnect.

13. The method of claim 12 wherein said diffusion barrier layer is a first diffusion barrier layer and said method further comprises:
forming a blanket second diffusion barrier overlying said second dielectric layer and formed within said opening in said second dielectric layer and contacting said conductive interconnect subsequent to etching said first diffusion barrier;
forming a blanket copper seed layer overlying and contacting said second diffusion barrier;
forming a copper layer to fill said opening in said second dielectric layer and contacting said copper seed layer; and
planarizing said copper layer which fills said opening in said second dielectric layer.

14. The method of claim 12 further comprising forming a diffusion barrier layer from a material selected from the group consisting of tantalum nitride and silicon oxycarbide during said formation of said first diffusion barrier.

15. The method of claim 12 further comprising forming a layer comprising a material selected from the group consisting of amorphous silicon, tungsten silicide, tungsten nitride, tungsten silicon nitride, titanium nitride, tantalum, tantalum nitride during said formation of said hard mask layer.

16. The method of claim 12 wherein said second dielectric layer has a thickness and said method further comprising etching between about 60% and about 90% of said thickness during said only partially etching said second dielectric layer at said first location.

17. The method of claim 12 further comprising etching said second dielectric layer with an etchant comprising CF₄ at a flow rate of between about 50 sccm and about 100 sccm, CHF₃ at a flow rate of between about 10 sccm and about 20 sccm, and argon at a flow rate of between about 40 sccm and about 100 sccm during said only partially etching said second dielectric layer at said first location.

18. The method of claim 12 further comprising etching said first polymer layer using a mixture of H₂SO₄ and H₂O₂ during said etching of said first polymer layer.

19. The method of claim 12 further comprising etching said second polymer using H₃PO₄ for a duration of about 180 seconds at a temperature of between about 30° C. and about 40° C. during said etching of said second polymer.

20. The method of claim 12 further comprising etching said second polymer using hydrofluoric acid for a duration of about 30 seconds at ambient temperature during said etching of said second polymer.
